(19) United States
(12) Patent Application Publication
(10) Pub. No.: US 2013/0153025 A1
(43) Pub. Date: Jun. 20, 2013

(54) METHOD FOR PRODUCING A SOLAR CELL HAVING A TEXTURED FRONT FACE AND CORRESPONDING SOLAR CELL

(71) Applicants: Giso Hahn, Konstanz (DE); Amir Dastgheib-Shirazi, Konstanz (DE)

(72) Inventors: Giso Hahn, Konstanz (DE); Amir Dastgheib-Shirazi, Konstanz (DE)

(73) Assignee: UNIVERSITÄT KONSTANZ, Konstanz (DE)

(21) Appl. No.: 13/819,205

(22) PCT Filed: Aug. 23, 2011
(86) PCT No.: PCT/EP11/64431

§ 371 Date: Feb. 26, 2013

(30) Foreign Application Priority Data
Aug. 27, 2010 (DE) 10 2010 035 582.8

(51) Int. Cl. H01L 31/18; H01L 31/0236

(52) U.S. Cl. CPC H01L 31/18; H01L 31/02366
USPC 136/256; 438/71

(57) ABSTRACT

The invention relates to a method for producing a solar cell and to a solar cell which can be produced accordingly. On a solar cell substrate, first a ridged texture, which may for example comprise pyramids produced by alkaline etching, is formed both on a front face and on a rear face of the solar cell substrate. Then an etching barrier layer is applied to the front face of the solar cell substrate. Next the texture on the rear face of, the solar cell substrate is smoothed by etching in an isotropically acting etching solution which for example contains acid, wherein the front face is protected by the etching barrier layer. Thus, ridged structures on the rear face can be avoided and in this way reflection can be increased and surface passivation can be improved, both of which can lead to an increased potential efficiency. At the same time an emitter layer formed over the entire surface of the solar cell substrate on the rear face can be removed during etching, so that electrical isolation of the front face contacts and the rear face contacts may be superfluous.

### FIELD OF THE INVENTION

The present invention relates to a method for producing a solar cell having a textured front face. The invention additionally relates to a solar cell, which may be produced by the method described.

### BACKGROUND OF THE INVENTION

Solar cells are usually produced on the basis of a semiconductor substrate such as, for example, a silicon wafer, and, frequently, a front face of the substrate that faces towards the sun when the cell is in use is textured. Texturing in this case is understood to mean a deliberate deviation from a flat realization of the front face. For example, etching may be applied to the front face by means of a so-called texturing etching method, in such a way that small pyramids remain on the surface. A surface textured in this way may have a lesser reflection than a non-textured surface, such that more light striking the front face is injected into the solar cell substrate, and consequently the efficiency of the solar cell may be increased.

US 2004/0259335 A1 describes a solar cell and a method for producing such a solar cell, in which a front face is masked and a rear face is etched back.

It has been observed, however, that, for example owing to the method by which a texture is conventionally realized in the case of solar cells, it is frequently necessary to accept certain disadvantages that may negatively affect the efficiency that may be achieved.

### SUMMARY OF THE INVENTION

A method for producing a solar cell is therefore sought in which, in particular, it is possible to reduce disadvantageous effects resulting from the formation of a texture at the surface of the solar cell. In particular, an efficiency is to be increased, as compared with solar cells similarly provided with a surface texture. It is furthermore of interest to propose a production method that is as simple as possible, by which positive effects may be achieved without additional, complicated method steps, and which is preferably compatible with process steps such as those conventionally used in the industrial production of solar cells.

This may be achieved with the production method and the solar cell according to the independent claims. Advantageous embodiments are described in the dependent claims.

According to a first aspect of the present invention, a method for producing a solar cell is described. The method comprises: providing a solar cell substrate; forming a texture at or on a front face and at or on a rear face of the solar cell substrate; applying an etching barrier layer to the front face of the solar cell substrate; and smoothing the texture on the rear face of the solar cell substrate by etching in an isotropically acting etching solution.

Aspects of the present invention may be considered to be based on, inter alia, the following observations: in the production of solar cells, for example on the basis of silicon wafers, the wafer surface is usually textured by etching with a texture etching solution, in order to achieve a reduction in the reflection of the front face. Conventionally in this case, the wafer is usually fully immersed in the texture etching solution, such that both its front face and its rear face become textured. During the texture etch, a portion of the wafer surface is etched away, the etching process, owing to an anisotropic action of the texture etching solution, being effected in such a way that small pyramids remain, which are typically in the range of a few micrometres in height. These pyramids create sloping flanks, on which incident light may be reflected multiple times and, owing to so-called light trapping, there is reduced reflection. Whereas this may be desirable on the front face of the solar cell, in order to minimise the reflection, it has been identified that the sharp edges of the pyramids on the rear face of the solar cell may have a disadvantageous effect.

Described here is a method for producing a solar cell that makes it possible to prevent sharp edges of a texture on the rear face of the solar cell. For this, it is proposed that the texture realized beforehand on the rear face of the solar cell substrate be subsequently smoothed by etching in an isotropically acting etching solution. The isotropically acting etching solution in this case may etch the material of the solar cell substrate to an equal extent in all directions, i.e. there is no preferred etching direction. “Smoothing” in this case may be understood to mean that the texture realized beforehand, having an angular, i.e. edged, structure such as, for example, a pyramid structure, is subsequently rounded by etching in the etching solution that contains acid. After smoothing, therefore, the edges of the texture structure no longer have flat surfaces that adjoin one another at an angle, but graduate into one another with a radius of curvature. The radius of curvature in this case may be, for example, in the order of magnitude of the dimensions, or greater than the dimensions, of individual texture elements such as, for example, individual pyramids of the original texture structure, i.e. in the range of, for example 0.1 to 10 μm.

It has been found that a solar cell whose textured rear face has been smoothed may have an increased rear-face reflection. This may have the result that light that has penetrated into the solar cell substrate from the front face is reflected better at the rear face, and therefore remains within the solar cell substrate instead of emerging at the rear face. This may be advantageous, particularly in the case of solar cells that do not have a separate rear-face reflector, for example in the form of an applied metal layer, on their rear face, and may be instrumental, in particular, in improving the quantum efficiency in the case of long wavelengths.

Further, it has been found that a smoothed rear face, particularly if coated with a dielectric layer for the purpose of surface passivation, has a lesser surface recombination than a textured rear face provided with sharp edges. Therefore, owing to the change in the surface morphology of the rear face of the solar cell that results from the smoothing of the texture, both effects may result in an improvement in the efficiency of the solar cell produced in the manner proposed.

It has been observed that such smoothing of the texture, particularly in the case of solar cell substrates composed of silicon, may preferably be achieved with an acid-containing etching solution. The acid-containing etching solution is intended in this case to act upon the material of the solar cell substrate. For example, the acid-containing etching solution may contain hydrofluoric acid (HF). An etching solution that is suitable, in particular, for silicon substrates is composed, for example, of hydrofluoric acid (HF), nitric acid (HNO₃) and water (H₂O). Unlike many basic, i.e. alkaline, etching solutions, etching solutions containing acid usually act isotropically, and may therefore be instrumental in etching for the purpose of rounding, and thereby smoothing, sharp-edged texture structures.

In order to protect the front face of the solar cell substrate during the etching process, it may be covered with an etching barrier layer. An etching barrier layer in this case may be understood to mean a layer applied, with a sufficient chemical etch resistance and a sufficient thickness and seal tightness, to the front face of the substrate, in order to protect this front face from being etched by the etching solution. For example, the etching barrier layer may be realized with a viscous paste. The viscous paste in this case may be waxy or liquid, a viscosity being developed in such a way that the paste may form a stable, impervious film over the front face of the substrate during the etching process.

The etching barrier layer may be applied, for example, by means of a screen printing technique or an ink-jet technique. Both the screen printing technique and the ink-jet technique constitute method techniques that are established techniques in the industrial production of solar cells and that for a long time have been reliably used, for example, to form metal contacts.

The etching performed for the purpose of smoothing the texture may be performed in such a way that less than 20 μm, preferably less than 10 μm, and more preferably less than 5 μm is removed from the rear face of the solar cell substrate. Thus, in comparison with other etching steps conventionally performed in the production of solar cells, such as those performed, for example, for removing sawing damage or for polishing the surface of the solar cell, significantly less material is removed from the surface of the solar cell. Particularly in view of the fact that progressively thinner substrates are used in the production of solar cells, it may be advantageous to remove as little substrate material as possible during the etching process, while it is still nevertheless necessary to achieve a sufficient smoothing of the structure on the rear face of the substrate. Removal of about 1-20 μm, preferably 3-10 μm on the rear face of the substrate has proved to be suitable for this.

As compared with other etching processes conventionally used in solar cell production, the process of etching for the purpose of smoothing the texture may be of short duration. For example, the etching may be performed in a period of less than 5 minutes, preferably less than 3 minutes, and more preferably less than 2 minutes. Such a short etching duration may be instrumental in rapid production of the solar cell as a whole.

During the etching process, the acid-containing etching solution may be substantially at room temperature, i.e., for example, in the range from 10° C. to 40° C., preferably in the range from 20° C. to 30° C. It may therefore be the case that there is no need for special tempering such as, for example, heating of the etching solution. This, too, may be instrumental in simplifying and accelerating the entire production method.

In one embodiment of the method, before the texture is smoothed, an emitter layer is realized both on the front face and on the rear face of the solar cell substrate. Since the front face is subsequently protected with the etching barrier layer, the emitter layer is removed only on the rear face of the solar cell substrate during the subsequent etching for the purpose of smoothing the texture. In this way, it is possible to produce a solar cell having an emitter layer only on its front face and possibly on the lateral edges of the solar cell substrate, the solar cell substrate, which otherwise serves as a base, on the rear face having been relieved of the emitter layer present there, owing to the etching step for the purpose of smoothing, such that the base may be contacted directly on the rear face. It is therefore no longer necessary, as in the case of many conventionally produced solar cells, for a parasitic emitter on the rear face of the substrate to be electrically isolated from the emitter on the front face, this conventionally having required additional method steps such as, for example, wet chemical emitter etching on one single face without masking, edge isolation by means of laser, edge isolation by means of plasma or edge separation by sawing. In other words, the method step of etching the rear face of the substrate for the purpose of smoothing the texture realized there may be used, at the same time, to etch away a parasitic emitter realized previously on the rear face of the substrate. Accordingly, it may be the case that additional method steps for electrically isolating the rear face of the substrate, contacted by the rear-face contacts, and the front face of the solar cell, contacted by the front-face contacts, become superfluous.

In a further embodiment of the production method, after the texture has been smoothed, a passivation layer is applied to the rear face of the solar cell substrate. A passivation layer in this case may be understood to be a layer that passivates the surface of the semiconductor substrate and therefore results in a reduced rate of surface recombination. A passivation layer may be, for example, a dielectric layer, formed with silicon nitride (SiₓN_{y}), silicon oxide (SiO₂), aluminium oxide (Al₂O₃) or amorphous silicon (a-Si). It has been observed that, particularly on rear faces of a solar cell whose texture has been smoothed in the manner previously described, such a passivation layer may have a particularly advantageous effect. In particular, it has been observed that a smoothed rear-face surface provided with a passivation layer has a lesser rate of surface recombination than a non-smoothed rear-face surface that has likewise been provided with a passivation layer and sharp edges.

In a further embodiment, the described smoothing of the rear face of the substrate may be combined with formation of a selective emitter. The selective emitter in this case may be realized by etching in an etching solution. A selective emitter in this case is understood to mean a layer doped in the manner of an emitter, the doping concentration of which varies locally. In other words, a homogeneously doped emitter layer may be generated first, and this may then be partially etched away locally. The etching barrier layer, which is deposited on the front face in any case, before the etching step provided to smooth the rear face, may be appropriately configured in this case such that, by means of this etching barrier layer, selective etching of the front face, and consequently generation of the selective emitter, may also be realized.

For example, the etching barrier layer (15) may have two partial layers, disposed above one another, that have differing resistance capabilities in respect of stripping solutions used to remove the partial layers.

According to a further aspect of the present invention, a solar cell is described, which has a solar cell substrate having an angular texture on a front face and having a smoothed texture on a rear face. Such a solar cell may be produced by the method described above. The angular texture on the front face in this case may have sharp edges, whereas the smoothed texture on the rear face may have rounded edges. However, the rear face of the solar cell in this case need not be completely smooth, i.e. flat, but may definitely have a kind of texture, in the form of an undulation, and therefore be uneven. However, the smoothed texture provided on the rear face is intended not to have sharp edges. Preferably, the rear face of the solar cell substrate is covered with a passivation layer.

The proposed production method and the proposed solar cell enable the following advantages, inter alia, to be achieved:
The solar cell provided with the smoothed texture on its rear face may have an improved efficiency, particularly if the rear face is additionally provided with a preferably dielectric passivation layer. This improved efficiency may result from an increased reflection on the rear face of the solar cell, as a result of the smoothed texture, and consequently as a result of an increased injection of light for the solar cell that results in an increase in the quantum efficiency of the solar cell in the longwave wavelength range. A surface-passivated rear-face surface provided with a smoothed texture may render possible an increased efficiency potential, particularly for solar cells that are contacted locally on their rear face.
The etching barrier layer deposited on the front face of the solar cell substrate may fully and reliably protect an emitter layer realized previously on the front face, such that the front-face emitter is not etched. In particular, if a viscous paste that is easy to apply and easy to remove is used for the etching barrier layer, no change in the sheet resistance of the front-face emitter is to be noted, even after the etching barrier layer is removed.
Only a small amount of material is etched away from the rear face of the solar cell substrate for the purpose of smoothing the texture. The etching process may therefore be performed with a short process duration. Despite the small loss of material, a significant increase in the rear-face reflection may be achieved as a result of smoothing the rear-face texture.
The smoothing of the rear-face texture may be combined with removal of a rear-face emitter. As a result of the removal of material during etching of the rear face for the purpose of smoothing the latter, the rear-face emitter is concomitantly removed at the same time. It is possible to dispense with separate electrical isolation of the parasitic rear-face emitter.
The method proposed here for smoothing the rear-face texture may optionally be combined with a method in which a so-called selective emitter is generated on the front face of the substrate. The selective emitter in this case may be generated in that the front face is partially protected by an etching barrier layer, and is then partially removed by etching back in the unprotected regions, such that emitter regions having a greater sheet resistance remain there. A single masking step, in which an etching barrier layer is applied selectively on the front face of the solar cell substrate, could be sufficient for the purpose of generating a selective emitter produced in such a manner, and for the purpose of smoothing the rear-face texture. Further, a single etching process could be sufficient to selectively etch back the emitter and smooth the rear-face texture.
The proposed method may make use of technologies that are cost-effective on an industrial scale, such as, for example, screen printing or ink-jet printing and wet chemical etching methods. These methods have already been in use for many years in the production of solar cells, and may be adapted without difficulty for the method presented.

It is pointed out that features and embodiments of the invention have been described herein partly in respect of the production method and partly in respect of the solar cell. However, persons skilled in the art will recognize that the corresponding features may also be transferred analogously to the solar cell and to the production method. In particular, the features described may also be combined with one another in any manner.

### BRIEF DESCRIPTION OF THE DRAWINGS

The aspects, features and advantages of the present invention that have been described above, and further aspects, features and advantages of the invention, become evident from the following description of specific embodiments, which description, however, is not to be construed as limiting of the invention, and through reference to the accompanying drawings.

FIG. 1 illustrates a sequence of process steps of a method for producing a solar cell according to an embodiment of the present invention.

FIG. 2 shows a schematic sectional view through a solar cell according to an embodiment of the present invention.

The drawings are merely schematic, and are not true to scale.

### DESCRIPTION OF PREFERRED EMBODIMENTS OF THE INVENTION

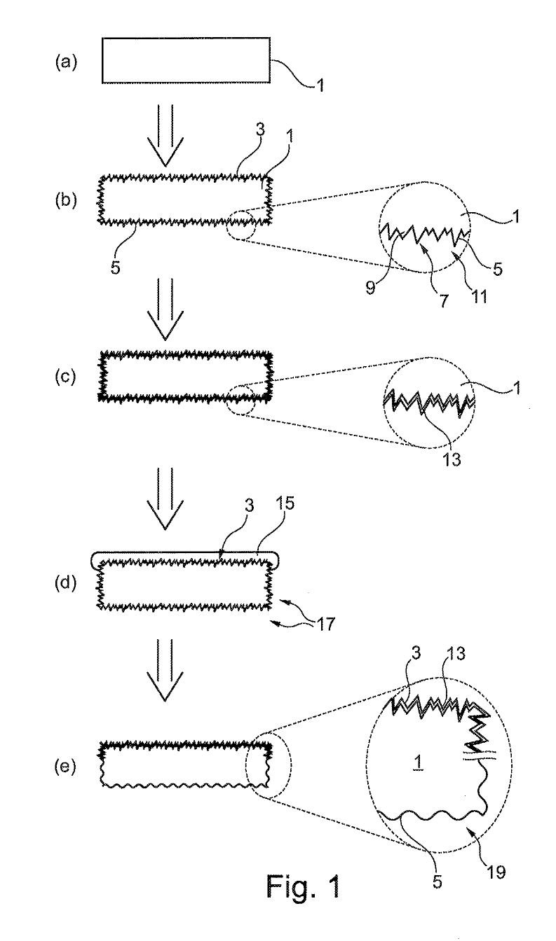

A method for producing a solar cell according to an embodiment of the present invention is to be described with reference to FIG. 1. It is pointed out that, in the figure, in particular, some process steps that are essential for the method according to the invention are represented schematically. The entire method for producing the solar cell may comprise further process steps. Some of such further process steps are stated, by way of example, in the following description. It is pointed out, however, that the process steps that are essential to the method, stated in the claims, may also be combined with other process steps to form an entire production sequence.

Firstly, in step (a), a solar cell substrate 1 is provided. This may be, for example, a thin silicon wafer, having a thickness of less than 200 μm. The solar cell substrate may be prepared, before further processing, by cleaning steps and etching steps, by means of which, for example, sawing damage caused during sawing of the substrate is removed.

In a subsequent step (b), a texture 7 is realized both on a front face 3 and on a rear face 5 of the solar cell substrate 1. For this purpose, the substrate 1 may be fully immersed in a hot alkaline etching solution containing, for example, potassium hydroxide (KaOH). The alkaline etching solution in this case is selected such that the surfaces of the solar cell substrate undergo anisotropic etching, such that small pyramid-type structures are realized thereon. For step (b), FIG. 1 in this case shows in the enlarged visualization shown on the right side clearly that, as a result of such an etching step, inter alia, a sharp-edged texture 7 is realized on the rear face 5. The pyramids 9 in this case are realized in an angular structure 11 on the rear face 5.

Alternatively, the solar cell substrate 1 may also be etched in a special acid solution having a mixture of hydrofluoric acid (HF), nitric acid (HNO₃) and water (H₂O), which may likewise result in a sharp-edged texture, owing to an anisotropic etching property. In this way, even multi-crystalline solar cell substrates may be textured.

In a step (c), the solar cell substrate 1 that has been textured in such a manner is then subjected to emitter diffusion. In this case, a thin emitter layer 13 forms on the entire surface of the solar cell substrate 1. For this purpose, dopants are diffused superficially into the base-type semiconducting solar cell substrate 1, in order to form a thin emitter layer 13 of the opposite semiconductor type. The emitter layer in this case extends over the entire surface of the solar cell substrate 1, including the front face 3 and the rear face 5.

Then, in a step (d), an etching barrier layer 15 is applied to the solar cell substrate, on the front face 3. The etching barrier layer 15 in this case may be applied in the form of a viscous paste, for example a waxy paste, by means of conventional screen printing techniques or ink-jet techniques, on the front face 3. For example, so-called ink-jet wax, as distributed, inter alia, under the name SunJet by Sun Chemical Corporation (GB), may be applied with a thickness of 5-10 μm on the front face 3 by means of an ink-jetter. Alternatively, a viscous paste, such as that distributed, inter alia, by Peters Lackwerke GmbH (Germany), may be applied with a thickness of 5-10 μm on the front face 3 by means of a screen printer.

Then, in a step (e), the solar cell substrate 1 that has been prepared in such a manner is immersed in an acid-containing etching solution. The regions protected by the etching barrier layer 15 are not attacked by the etching solution in this case. However, the exposed regions 17 are attacked and etched away by the isotropically acting, acid etching solution. The acid etching solution in this case may contain hydrofluoric acid (HF), nitric acid (HNO₃) and acetic acid (CH₃COOH), for example in the ratio 19:60:20. The etching solution may additionally contain water (H₂O). The temperature of the etching solution in this case may correspond approximately to room temperature. The etching process may last less than 2 minutes. In this case, empirically, a layer having a thickness of less than 10 μm is removed from the exposed regions 17.

Since the etching process in the acid-containing etching solution is isotropic, the texture 7 that was previously realized with sharp edges becomes rounded, and thereby smoothed. At the same time, the previously diffused-in emitter layer 13, which typically is only a few 100 nm thick, is removed during the etching step.

The etching process and the etching barrier layer 15 may be specially adapted in order that, in addition to the smoothing on the rear face of the substrate, a selective emitter may be realized on the front face of the substrate. The positionally selective etching back of the emitter layer 13 on the front face 3 of the substrate is effected at nanometre scale. The etching of the rear face 5, on the other hand, is effected at micrometre scale. The etching medium and/or the etching duration should therefore be adapted for the rear face.

The etching of the texture 7 on the rear face 5, to render it smooth, and the selective etching-back of the emitter layer 13 on the front face 3 may be realized by a single masking step, as described in the following: in this case, use is made of differing degrees of stripping of two etching masks, which serve as partial layers of the etching barrier layer 15. A first, more resistant mask serves to protect the low ohmic resistance region of the selective emitter. A second, full-surface etching mask over the first mask serves to protect the entire front face 3 as the rear face 5 is being etched to render it smooth. After the rear face 5 has been etched, the full-surface etching mask is removed by wet chemical stripping. Owing to its greater resistance capability (e.g. hardened etching mask), the partial etching mask underneath remains unaffected by the first stripping, so as to remain effective for the selective emitter etching step. This masking step is followed by the wet chemical etching of the emitter layer 13 and the subsequent stripping of the partial mask in an adapted stripping solution for hardened etching masks.

A further possibility would be to use only one mask, instead of two masks, as described above. In this case, only the mask for the selective etching-back of the emitter layer 13 would then be applied, e.g. with an additional ‘line’ at the edge of the front face 3. Then, in the smooth-etching step that follows, the solar cell substrate is not completely immersed in the etching solution, but floats only with the rear face 5 on the solution, such that the front face 3 does not come into contact with the etching solution. After that, the etching-back of the emitter may be effected by full immersion of the wafer.

After the etching process, the etching barrier layer 15 is removed again. For this purpose, the solar cell substrate 1, provided with the etching barrier layer 15, may be immersed in a slightly alkaline solution, and the etching barrier layer 15 stripped from the substrate 1. The result is thus the structure shown in FIG. 1, step (e), in which a sharp-edged texture 7, including the emitter layer 13 diffused therein, has remained on the front face 3 of the solar cell substrate 1, and in which a rounded, smoothed texture 19, without a diffused-in emitter layer, may be seen on the rear face 5. The rounded texture 19 does not have sharp edges. Owing to the reduced light-trapping effect of such a rounded texture, the reflection of the rear face is increased in comparison with the angularly textured front face.

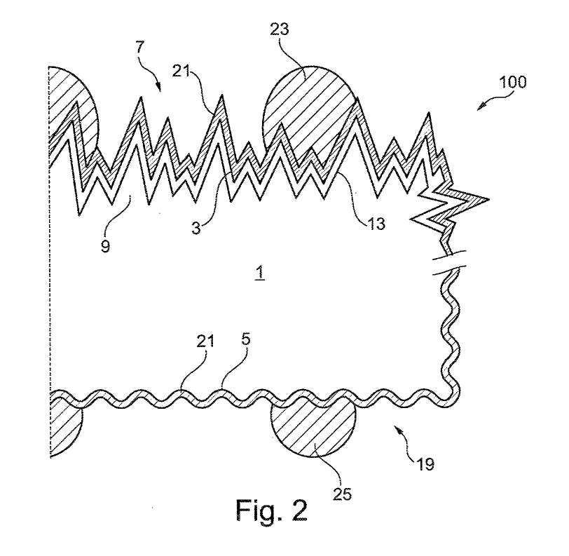

In subsequent process steps, further layers may be deposited on the solar cell substrate 1 that has been textured in such a manner and provided with a front-face emitter layer 13, and metal contacts may be applied in order, ultimately, to achieve a solar cell 100, such as that represented in FIG. 2. In this case, an additional passivation layer 21, in the form of a dielectric layer, for example composed of silicon nitride, silicon oxide or aluminium oxide, is deposited on the angularly textured front face 3 and on the smoothed, textured rear face 5. On the front face 3, the passivation layer 21 in this case covers the emitter layer 13. At the rear face 5, the passivation layer 21 directly covers the base of the solar cell substrate 1. Owing to the dielectric layer and the rounded, smoothed texture 19 on the rear face 5 of the solar cell substrate 1, there is reduced surface recombination.

Front-face contacts 23 and rear-face contacts 25 may contact the solar cell substrate 1 locally. The front-face contacts 23 in this case contact the emitter layer 13. The front-face contacts 23 may be produced, for example, by screen printing, wherein linear metal structures may be printed on to the front face 3 and then fired-through, through the passivation layer 21. The firing-through process causes the metal contained in the front-face contacts 23 to come directly into contact with the emitter layer 13 (to aid clarity, not represented in the figure). The rear-face contacts 25 may likewise be realized as linear structures and applied to the passivation layer 21 by means of screen printing, and then fired-through, through the passivation layer.

By means of the production method presented, it has already been possible to produce large-area (125×125 mm²) solar cells, by a screen printing method suitable for industrial production, on p-type Cz silicon having a resistivity of 2.5 ohms-cm. The rear face in this case had a full-surface aluminium BSF (back surface field). The front face had a homogeneous emitter. Efficiencies of up to 18.4% were achieved, a parallel resistance of the solar cell of approximately 10,000 ohms-cm² having been measured, this confirming successful removal of the emitter on the rear face of the substrate without the creation of short circuits.

Also already produced at laboratory scale were solar cells provided with a dielectrically passivated rear face. Efficiencies of over 20% were achieved on FZ silicon in this case. Measurements of the reflection at the rear face of the substrate made it possible to confirm that the reflection, which averaged about 10% in the case of alkaline-etched surfaces, was greatly increased after the smoothing of the textured rear-face surfaces, and in some cases averaged up to about 35%. At the same time, it was possible to test various passivation layers, and a significant increase in the effective minority charge-carrier lifetime was measured in the case of the smooth-etched substrates, as compared with the non-etched substrates having a sharp-edge rear-face texture.

Finally, it is pointed out that the terms “comprise”, “have” etc. are not intended to exclude the presence of further, additional elements. The term “a” also does not exclude the presence of a plurality of elements or objects. Moreover, further method steps, in addition to the method steps stated in the claims, may be necessary or advantageous, in order, for example, to produce an ultimately finished solar cell. The references in the claims serve merely to aid legibility, and are not intended to limit the scope of protection of the claims in any way.

### LIST OF REFERENCES

1 solar cell substrate
3 front face
5 rear face
7 texture
9 pyramids
11 angular structure
13 emitter layer
15 etching barrier layer
17 exposed regions
19 smoothed texture
21 passivation layer
23 front-face contacts
25 rear-face contacts

1. Method for producing a solar cell, comprising:
providing a solar cell substrate;
forming a texture at a front face and at a rear face of the solar cell substrate;
applying an etching barrier layer to the front face of the solar cell substrate; and
smoothing the texture at the rear face of the solar cell substrate by etching in an isotropically acting etching solution for removal of about 1 μm to 20 μm of substrate material, the texture being realized with an angular structure, and edges of the texture structure being rounded, in the form of an undulation, as the texture is being smoothed.

2. Method according to claim 1, wherein the isotropically acting etching solution contains acid.

3. Method according to claim 2, wherein the acid-containing etching solution contains hydrofluoric acid.

4. Method according to claim 1, wherein the etching barrier layer is realized with a viscous paste.

5. Method according to claim 1, wherein the etching barrier layer is applied by a screen printing technique or an ink-jet technique.

6. Method according to claim 1, wherein the etching is performed in such a way that less than 20 μm is removed from the rear face of the solar cell substrate.

7. Method according to claim 1, wherein the etching is performed in a period of less than 5 minutes.

8. Method according to claim 1, wherein the etching solution during etching is at a temperature in the range from 10° C. to 40° C.

9. Method according to claim 1, wherein, before the texture is smoothed, an emitter layer is realized both at the front face and at the rear face of the solar cell substrate, and wherein the emitter layer is removed at the rear face of the solar cell substrate as the texture is being smoothed.

10. Method according to claim 1, wherein, after the texture has been smoothed, a passivation layer is applied to the rear face of the solar cell substrate.

11. Method according to claim 1, wherein, after the etching barrier layer has been applied to the front face of the solar cell substrate, a selective emitter is realized by etching in an etching solution.

12. Method according to claim 11, wherein the etching barrier layer has two partial layers, disposed above one another, that have differing resistance capabilities in respect of stripping solutions used to remove the partial layers.

13. Solar cell comprising:
a solar cell substrate, which at a front face has an angular texture and which at a rear face has a rounded texture in the form of an undulation.

14. Solar cell according to claim 13, further comprising a selective emitter at the front face of the solar cell substrate.

15. Method according to claim 1, wherein the texture at the rear face is smoothed by removal of 3 μm to 20 μm of substrate material.

16. Method according to claim 1, wherein the texture at the rear face is smoothed by removal of 3 μm to 10 μm of substrate material.
